(19) United States
(12) Patent Application Publication
(10) Pub. No.: US 2026/0332130 A1
(43) Pub. Date: Oct. 22, 2026

(54) IMPEDANCE ADJUSTMENT CIRCUIT

(71) Applicant: INDUSTRIAL COOPERATION FOUNDATION JEONBUK NATIONAL UNIVERSITY, Jeollabuk-do (KR)

(72) Inventors: Cheon Yong LIM, Jeollabuk-do (KR); Yong Sug SUH, Jeollabuk-do (KR); Hong Min KIM, Gwangju (KR)

(73) Assignee: INDUSTRIAL COOPERATION FOUNDATION JEONBUK NATIONAL UNIVERSITY, Jeollabuk-do (KR)

(21) Appl. No.: 19/122,548

(22) PCT Filed: Sep. 21, 2023
(86) PCT No.: PCT/KR2023/014411

§ 371 Date: Apr. 18, 2025

(30) Foreign Application Priority Data
Oct. 21, 2022 (KR) 10-2022-0136328

(51) Int. Cl. H03H 11/30; H01J 37/32

(52) U.S. Cl. CPC H03H 11/30; H01J 37/32183; H03H 11/28

(57) ABSTRACT

An impedance adjustment circuit adjusts an impedance by changing an equivalent capacitance. The circuit includes: a unit leg configured to adjust the equivalent capacitance based on a connection with a target capacitor; an adjustment capacitor connected to a reference voltage rail and, via a first inductor, to a diode connected to an RF rail; a leg voltage source and two switches controlling the connection path; a parallel inductor; and a control unit. The adjustment capacitor has a capacitance at least five times greater than the junction capacitance of the diode.

### TECHNICAL FIELD

The present disclosure generally relates to an impedance adjustment circuit.

### BACKGROUND ART

Semiconductor manufacturing processes include various unit processes, and representative examples of these unit processes include an etching process and a deposition process. Today's etching and deposition processes are representative examples of processes that utilize plasma. In these processes, plasma equipment is used, and the impedance of an input side is matched with the impedance of a load side to ensure maximum power transmission to the load side.

Since a plasma load is a load that continuously changes in value depending on the type and amount of gas used in a chamber and whether plasma is generated, an impedance matching circuit is essential to continuously match the impedance with that of the input side to cope with these characteristics.

### DISCLOSURE

### Technical Problem

In conventional impedance matching circuits, a vacuum variable capacitor that mechanically adjusts capacitance has been used. However, the vacuum variable capacitor has an issue of slower adjustment time because the capacitance is mechanically varied. The time required to mechanically change the capacitance accounts for 30% of the total etching process time.

In addition, it is common to perform semiconductor processes by using RF voltage supplied through an RF rail to form plasma. However, in conventional technology, there was a problem that the RF voltage penetrated into the driving circuit and acted as unintended noise, causing malfunction of the driving circuit.

The present embodiment aims to overcome the challenges of the related art. In other words, one of the objectives of the present embodiment is to provide an impedance adjustment circuit capable of rapidly changing the capacitance electrically and reducing the influence of RF voltage.

### Technical Solution

One aspect of the present invention provides an impedance adjustment circuit configured to adjust an impedance by adjusting an equivalent capacitance, the impedance adjustment circuit comprising: a unit leg configured to adjust the equivalent capacitance according to a connection with a capacitor, the unit leg comprises: an adjustment capacitor having one electrode connected to a reference voltage rail and connected to the capacitor equivalently to adjust the equivalent capacitance, a leg voltage source, two switches connected in series with the leg voltage source, a first inductor having one electrode connected to a node where the two switches are connected and the other electrode connected to the other electrode of the adjustment capacitor, and a diode having an anode connected to an RF rail, an RF voltage is provided to the anode and a cathode connected to the other electrode of the first inductor, and a junction capacitance is formed between the anode and the cathode, a parallel inductor connected in parallel with said unit leg; and a control unit that controls the legs so that the above equivalent capacitance changes, wherein a capacitance of the adjustment capacitor is 5 times or more greater than the capacitance of the junction capacitor.

According to one aspect of the present embodiment, the impedance adjustment circuit further comprises: a compensation voltage source connected to the parallel inductor in series.

According to one aspect of the present embodiment, the capacitor has one electrode connected to the RF rail and the other electrode connected to the reference voltage rail.

According to one aspect of the present embodiment, a voltage provided by the leg voltage source is greater in magnitude than the RF voltage provided to the RF rail.

According to one aspect of the present embodiment, the capacitance of the adjustment capacitor is 7 times or more greater than the capacitance of the junction capacitor.

According to one aspect of the present embodiment, the adjustment capacitor is connected in parallel with the capacitor through the diode, so that the equivalent capacitance is adjusted.

According to one aspect of the present embodiment, the two switches include a first switch connected to the reference voltage rail and a second switch connected to the leg voltage source, and when the second switch is blocked and the first switch is conducting, the adjustment capacitor and the capacitor are equivalently connected in parallel, so that the equivalent capacitance is adjusted.

According to one aspect of the present embodiment when the first switch is blocked and the second switch is conducting, the connection between the adjustment capacitor and the capacitor is equivalently blocked.

According to one aspect of the present embodiment, the unit leg may be provided as a plurality of unit legs connected in parallel.

According to one aspect of the present embodiment, the adjustment capacitors included in the plurality of unit legs may have different capacitances.

According to one aspect of the present embodiment, the adjustment capacitors included in the plurality of unit legs may have the same capacitances.

According to one aspect of the present embodiment, the control unit controls a connection of the adjustment capacitor included in at least one of the plurality of unit legs to be connected to the capacitor equivalently.

According to one aspect of the present embodiment, the diode may be a P-type-intrinsic-N-type (PIN) diode.

### Advantageous Effects

According to the present embodiment, there is an advantage in that capacitance can be rapidly changed through a control signal, thereby improving semiconductor productivity.

### DESCRIPTION OF DRAWINGS

FIG. 1 is a diagram illustrating one embodiment of an impedance adjustment circuit according to the present embodiment.

FIG. 2 is a diagram for explaining the operation of the present embodiment in the first phase in which the tuning capacitance is not in effect.

FIG. 3 is a diagram for explaining the operation of the present embodiment in the second phase in which the tuning capacitance is in effect.

FIG. 4 is a diagram that exemplifies an impedance tuning circuit that forms multiple unit legs.

### MODES OF THE INVENTION

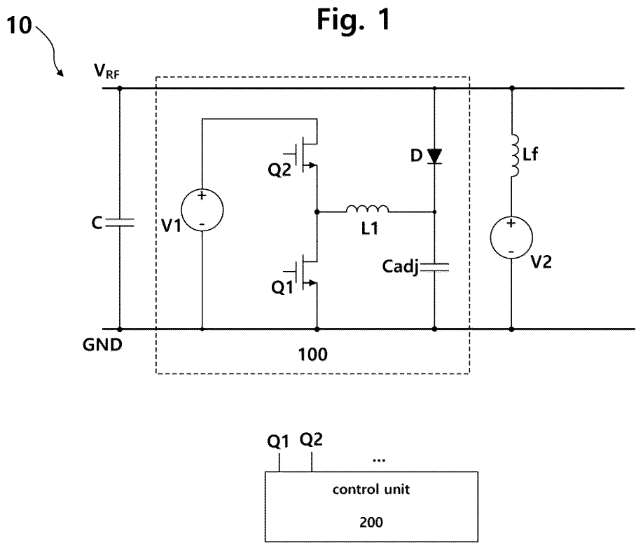

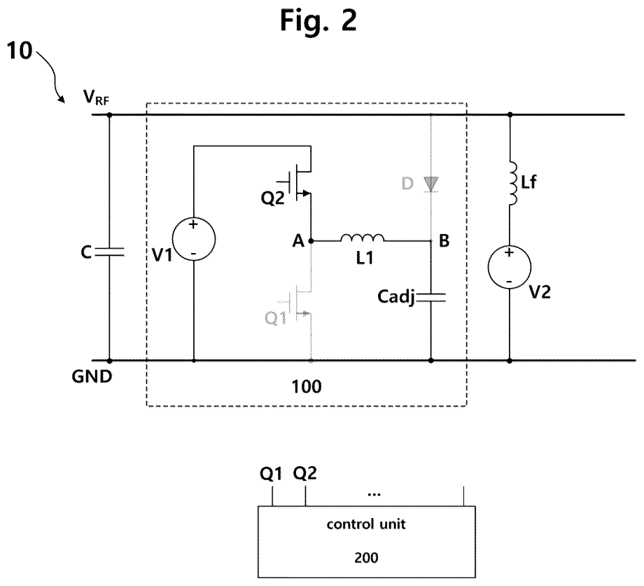

Hereinafter, the present embodiment will be described with reference to the accompanying drawings. FIG. 1 is a diagram illustrating one embodiment of an impedance adjustment circuit according to the present embodiment. Referring to FIG. 1, an impedance adjustment circuit 10 is an impedance adjustment circuit that adjusts impedance by adjusting equivalent capacitance and includes a capacitor C, a unit leg 100 that changes the equivalent capacitance depending on a connection with the capacitor C, a control unit 200 that controls the leg to change the equivalent capacitance, and an inductor Lf. As will be described below, a plurality of legs 100 may be connected in parallel and the inductor Lf may be connected to a compensation voltage source V2 (see FIGS. 2-4) in series.

As illustrated in the embodiment, a voltage provided by a leg voltage source V1 may be greater in magnitude than a radio frequency (RF) voltage V_{RF} supplied through an RF rail. Thus, when the RF voltage V_{RF} is applied to an anode of a diode D and the voltage provided by the leg voltage source V1 is applied to a cathode of the diode D, the diode may be blocked.

In the illustrated embodiment, the diode D may be a P-type-intrinsic-N-type (PIN) diode. The PIN diode is a diode formed by interposing an intrinsic semiconductor between a P-type doped semiconductor and an N-type doped semiconductor. The capacitance of the junction capacitor formed in the PIN diode has a lower capacitance value than the junction capacitance of the PN diode formed by the junction of a P-type semiconductor and an N-type semiconductor, and thus, as described below, it can provide a better performance in present embodiment.

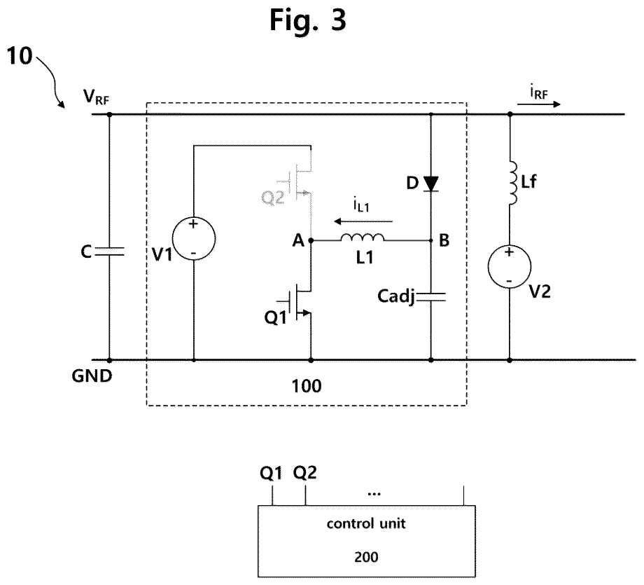

FIGS. 2 and 3 are drawings for explaining the operation of the impedance adjustment circuit 10 according to present embodiment in the first phase in which the adjustment capacitance is not in effect and in the second phase in which the adjustment capacitance is in effect, respectively. FIG. 2 is a drawing for explaining the operation of the embodiment in the first phase. Referring to FIG. 2, the control unit 200 controls switches Q1 and Q2 by providing control signals. In the first phase illustrated in FIG. 2, the control unit 200 provides control signals to block switch Q1 and conduct switch Q2. In the illustrated embodiment, switches Q1 and Q2 may be NMOS transistors, and in the other embodiment, which is not illustrated, switches Q1 and Q2 may be implemented as semiconductor switches such as PMOS transistors. In the illustrated embodiment, the impedance matching circuit 10 further includes a compensation voltage source V2. The compensation voltage source V2 provides a compensation voltage to compensate for the voltage drop that is formed across a diode D1 and a switch Q1 in the second phase, which will be described later.

The control unit 200 may provide a control signal in a logic low state to a gate electrode of the switch Q1 and a control signal in a logic high state to a gate electrode of the switch Q2, thereby turning off the switch Q1 and turning on the switch Q2.

When switch Q2 is turned on and the transient state is passed and the steady state is reached, the average voltage across the inductor is 0, due to voltage—second balance. Accordingly, in the steady state, there is no voltage difference between nodes A and B across the inductor L1.

Since the cathode of the diode D is connected to the node B, the voltage provided by the leg voltage source V1 is provided to the cathode, and the RF voltage V_{RF} is provided to the anode of the diode D from the RF rail. V1, the voltage provided by the leg voltage source V1, is greater than V_{RF}, the voltage provided by the RF rail. Accordingly, a reverse voltage is applied to the diode D, which causes the diode D to be blocked.

As described above, a parasitic capacitor formed in the diode D has a low capacitance value, thereby forming a high impedance. In the first phase, the diode D is blocked, but an RF voltage is formed at the B node by the voltage division of the capacitance Cj and the capacitance of the adjustment capacitor Cadj.

In the prior art, a resonant circuit resonating at RF frequency was used to bypass the high-frequency voltage formed at one end of the inductor to the ground voltage rail GND in order to bypass the RF signal to the ground rail at RF frequency. However, the frequency error occurred due to the error in the inductance and capacitance of the inductor and capacitor that form the resonant circuit, and the desired RF signal bypass effect could not be achieved.

In present embodiment, the voltage divider formed by the junction capacitor Cj and the adjustment capacitor Cadj of the diode is used to control the RF voltage formed at the B node. The following equation calculates the reactance of the capacitor.

$$X = \frac{1}{j ω C} \qquad [ Equation 1 ]$$

(j: unit imaginary number, w: angular velocity, C: capacitance)

As shown in Equation 1, the reactance of a capacitor is inversely proportional to the capacitance of the capacitor. If the capacitance of the adjustment capacitor Cadj is significantly larger than the junction capacitance Cj of the diode, the voltage VB formed at the B node can be expressed as shown in Equation 2 below according to the principle of voltage division.

$${V}_{B} = \frac{{X}_{adj}}{{X}_{j} + {X}_{adj}} = \frac{{C}_{j}}{{C}_{adj} + {c}_{j}} \qquad [ Equation 2 ]$$

(VB: voltage at node B, X_{adj}: reactance of adjustment capacitor, Xⱼ: reactance of junction capacitor)

In other words, the magnitude of the RF voltage formed at the B node corresponds to the magnitude of the capacitance Cj of the junction capacitor relative to the sum of the capacitances Cadj of the adjustment capacitor and Cj of the junction capacitor. Therefore, by using an adjustment capacitor Cadj with a larger capacitance than the junction capacitor Cj formed in the diode, the magnitude of the RF voltage formed at the B node can be reduced.

In one embodiment, the capacitance of the adjustment capacitor Cadj can be at least five times greater than the capacitance of the junction capacitor Cj, and preferably seven times or more. By adjusting the capacitance of the adjustment capacitor in this way, the effect of the RF voltage acting as noise in the driving circuit can be reduced.

FIG. 3 is a diagram for describing the operation of the present embodiment during the impedance second phase. Referring to FIG. 3, in the second phase, the control unit 200 provides control signals to turn off the switch Q2 and conduct the switch Q1. An inductor current I_{L1}, which is a direct current and greater than the maximum value of an RF current IRF, flows through the inductor L1, and the RF current IRF and the current I_{L1} are combined and flow through the diode D. Thus, a current greater than zero always flows through the diode D, thereby causing the diode D to conduct.

As the diode D conducts, the capacitor C and the adjustment capacitor Cadj are connected in parallel. Thus, an equivalent capacitance Ceq is formed as the sum of the capacitances of the two capacitors, i.e., C+Cadj, and may be formed to achieve the desired capacitance, thereby performing impedance adjustment.

In the impedance adjustment phase, in a path in which the diode D, the inductor, and the switch Q1 are connected, a forward voltage drop is formed across the diode D1 when the diode D1 conducts, and a voltage drop is formed due to a conduction resistance when a current flows through the switch Q1.

In order to compensate for the voltage drops formed in the diode D1 and the switch Q1, a compensation voltage source V2 provides a compensation voltage. A magnitude of the compensation voltage may correspond to the sum of the forward voltage drop of the diode D1 and the voltage drop caused by the conduction resistance of the switch Q1. In addition, the compensation voltage source V2 is connected in series with an inductor Lf. In the second phase, when the leg 100 is in a steady state, the inductor Lf is equivalent to a conducting wire due to the voltage—second balance.

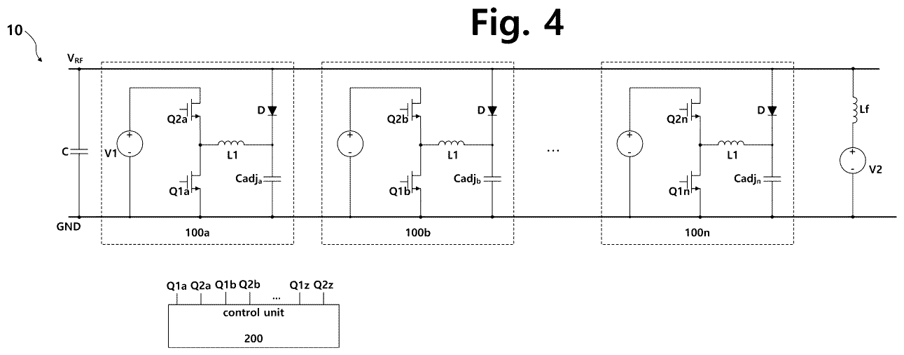

FIG. 4 is a diagram illustrating an impedance adjustment circuit formed by a plurality of unit legs 100. Referring to FIG. 4, the illustrated impedance adjustment circuit includes a plurality of unit legs 100a, 100b, . . . , and 100n. Capacitances of adjustment capacitors Cadjₐ, Cadj_{b}, . . . , and Cadjₙ included in the unit legs 100a, 100b, . . . , and 100n, respectively, may be different from one another or the same with each other.

Accordingly, the control unit 200 may select the unit leg that includes a capacitance matched to an impedance of a load (not shown) so that maximum power can be transmitted according to the impedance of the load and provide control signals to activate the selected leg and connect the capacitor C and the corresponding adjustment capacitor in parallel, thereby performing impedance matching. In one embodiment, a plurality of adjustment capacitors can be connected to the target capacitor C.

According to the related art, an independent power source is formed in each unit capacitance adjustment part. However, in the related art, the independent power source utilizes an isolation transformer to reduce the impact of noise, but when the isolation transformer is included in each unit capacitance adjustment part, the number of components increases, which results in issues such as increased volume and higher circuit manufacturing cost.

However, according to the present embodiment, by using a single inductor and compensation voltage source to compensate for the voltage drop formed in the selected unit leg, it is possible to reduce the product volume compared to the related art and decrease the number of components in the circuit, thereby providing an economic advantage.

Although the present invention has been described with reference to the embodiments illustrated in the drawings to aid in understanding of the present invention, these are for illustrative purposes only, and it should be understood that various alterations and other equivalent embodiments may be made by those skilled in the art. Therefore, the true technical scope of the present invention should be determined only by the appended claims.

1. An impedance adjustment circuit configured to adjust an impedance by adjusting an equivalent capacitance, the impedance adjustment circuit comprising:
a unit leg configured to adjust the equivalent capacitance according to a connection with target capacitor, the unit leg comprises:
an adjustment capacitor having one electrode connected to a reference voltage rail and connected to the capacitor equivalently to adjust the equivalent capacitance,
a leg voltage source,
two switches connected in series with the leg voltage source,
a first inductor having one electrode connected to a node where the two switches are connected and the other electrode connected to the other electrode of the adjustment capacitor, and
a diode having an anode connected to an RF rail, an RF voltage is provided to the anode and a cathode connected to the other electrode of the first inductor, and a junction capacitance is formed between the anode and the cathode,
a parallel inductor connected in parallel with said unit leg; and
a control unit that controls the legs so that the above equivalent capacitance changes,
wherein a capacitance of the adjustment capacitor is at least 5 times greater than the capacitance of the junction capacitor.

2. The impedance adjustment circuit of claim 1, wherein the impedance adjustment circuit further comprises:
a compensation voltage source connected to the parallel inductor in series.

3. The impedance adjustment circuit of claim 1, wherein the capacitor has one electrode connected to the RF rail and the other electrode connected to the reference voltage rail.

4. The impedance adjustment circuit of claim 1, wherein a voltage provided by the leg voltage source is greater in magnitude than the RF voltage provided to the RF rail.

5. The impedance adjustment circuit of claim 1, wherein the capacitance of the adjustment capacitor is at least 5 times greater than the capacitance of the junction capacitor.

6. The impedance adjustment circuit of claim 1, wherein the adjustment capacitor is connected in parallel with the capacitor through the diode, so that the equivalent capacitance is adjusted.

7. The impedance adjustment circuit of claim 1, wherein
the two switches include a first switch connected to the reference voltage rail and a second switch connected to the leg voltage source, and
when the second switch is blocked and the first switch is conducting, the adjustment capacitor and the capacitor are equivalently connected in parallel, so that the equivalent capacitance is adjusted.

8. The impedance adjustment circuit of claim 7, wherein when the first switch is blocked and the second switch is conducting, the connection between the adjustment capacitor and the capacitor is equivalently blocked.

9. The impedance adjustment circuit of claim 1, wherein the unit leg is provided as a plurality of unit legs connected in parallel.

10. The impedance adjustment circuit of claim 9, wherein the adjustment capacitors included in the plurality of unit legs have different capacitances.

11. The impedance adjustment circuit of claim 9, wherein the adjustment capacitors included in the plurality of unit legs have same capacitances.

12. The impedance adjustment circuit of claim 9, wherein the control unit controls a connection of the adjustment capacitor included in at least one of the plurality of unit legs to be connected to the capacitor equivalently.

13. The impedance adjustment circuit of claim 1, wherein the diode is a P-type-intrinsic-N-type (PIN) diode.
